(19) United States
(12) Patent Application Publication
(10) Pub. No.: US 2024/0085125 A1
(43) Pub. Date: Mar. 14, 2024

(54) IMMERSION-TYPE HEAT DISSIPATION STRUCTURE HAVING HIGH DENSITY HEAT DISSIPATION FINS

(71) Applicant: AMULAIRE THERMAL TECHNOLOGY, INC., New Taipei City (TW)

(72) Inventors: TZE-YANG YEH, New Taipei City (TW); CHING-MING YANG, New Taipei City (TW); CHUN-TE WU, New Taipei City (TW)

(21) Appl. No.: 17/945,066

(22) Filed: Sep. 14, 2022

(51) Int. Cl. F28F 3/04; F28D 21/00

(52) U.S. Cl. CPC F28F 3/048; F28D 21/00; F28D 2021/0029; F28F 2215/00

(57) ABSTRACT

An immersion-type heat dissipation structure having high density heat dissipation fins is provided, which includes a heat dissipation substrate and the plurality of sheet-like heat dissipation fins. A thickness of the heat dissipation substrate is from 2 mm to 6 mm, and a bottom surface of the heat dissipation substrate contacts a heating element immersed in a two-phase coolant. The sheet-like heat dissipation fins are integrally formed on an upper surface of the heat dissipation substrate and arranged in high density. A length, a width, and a height of at least one of the sheet-like heat dissipation fins are from 60 mm to 120 mm, from 0.1 mm to 0.5 mm, and from 3 mm to 10 mm, respectively. Further, a distance between at least two of the sheet-like heat dissipation fins that are arranged in parallel to each other is from 0.1 mm to 0.5 mm.

### FIELD OF THE DISCLOSURE

The present disclosure relates to a heat dissipation structure, and more particularly to an immersion-type heat dissipation structure having high density heat dissipation fins.

### BACKGROUND OF THE DISCLOSURE

An immersion cooling technology is to directly immerse heat producing elements (such as servers and disk arrays) into a coolant that is non-conductive, and heat generated from operation of the heat producing elements is removed through an endothermic gasification process of the coolant. Therefore, how to dissipate heat more effectively through the immersion cooling technology has long been an issue to be addressed in the industry.

### SUMMARY OF THE DISCLOSURE

In response to the above-referenced technical inadequacy, the present disclosure provides an immersion-type heat dissipation structure having high density heat dissipation fins.

In one aspect, the present disclosure provides an immersion-type heat dissipation structure having high density heat dissipation fins. The immersion-type heat dissipation structure includes a heat dissipation substrate and the plurality of sheet-like heat dissipation fins. A thickness of the heat dissipation substrate is from 2 mm to 6 mm, and a bottom surface of the heat dissipation substrate is in contact with a heating element immersed in a two-phase coolant. The plurality of sheet-like heat dissipation fins are integrally formed on an upper surface of the heat dissipation substrate and arranged in high density. A length of at least one of the plurality of sheet-like heat dissipation fins is from 60 mm to 120 mm, a width of at least one of the plurality of sheet-like heat dissipation fins is from 0.1 mm to 0.5 mm, and a height of at least one of the plurality of sheet-like heat dissipation fins is from 3 mm to 10 mm A distance between at least two of the plurality of sheet-like heat dissipation fins that are arranged in parallel to each other is from 0.1 mm to 0.5 mm. A first predetermined ratio between the distance and the width ranges from 0.5:1 to 2:1, a second predetermined ratio between the height and the width ranges from 6:1 to 50:1, and a third predetermined ratio between the height and the distance ranges from 6:1 to 50:1. The plurality of sheet-like heat dissipation fins are arranged to have an arrangement width, and the arrangement width is between 50 mm and 80 mm.

In certain embodiments, the plurality of sheet-like heat dissipation fins and the heat dissipation substrate are immersed in a sink filled with the two-phase coolant. The two-phase coolant is a FLUORINERT™ that has a low boiling point, and the boiling point of the two-phase coolant ranges from 35° C. to 60° C.

In certain embodiments, the heat dissipation substrate is made of one of copper, copper alloy, and aluminum alloy.

In certain embodiments, the immersion-type heat dissipation structure further includes a thin surface layer. The thin surface layer is formed on at least one of the upper surface of the heat dissipation substrate and a surface of the plurality of sheet-like heat dissipation fins.

In certain embodiments, the thin surface layer is one of a surface plating layer and a surface coating layer, and is made of one of nickel, titanium, and stainless steel.

In certain embodiments, the heat dissipation substrate has a plurality of vertical through holes formed thereon, and the plurality of vertical through holes vertically penetrate the heat dissipation substrate.

In certain embodiments, after the plurality of sheet-like heat dissipation fins are integrally formed on the upper surface of the heat dissipation substrate, the plurality of sheet-like heat dissipation fins are at least partially removed through a second processing operation such that at least one portion of the plurality of sheet-like heat dissipation fins and the remaining sheet-like heat dissipation fins do not have a same height, or the plurality of sheet-like heat dissipation fins on at least one region of the upper surface of the heat dissipation substrate are completely removed through the second processing operation.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a side view of an immersion-type heat dissipation structure according to a first embodiment of the present disclosure;

FIG. 2 is an enlarged view of part II of FIG. 1;

FIG. 3 is a top view of the immersion-type heat dissipation structure according to the first embodiment of the present disclosure;

FIG. 4 is a schematic view of the immersion-type heat dissipation structure according to a second embodiment of the present disclosure;

FIG. 5 is a perspective view of the immersion-type heat dissipation structure according to a third embodiment of the present disclosure; and

FIG. 6 is a perspective view of the immersion-type heat dissipation structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

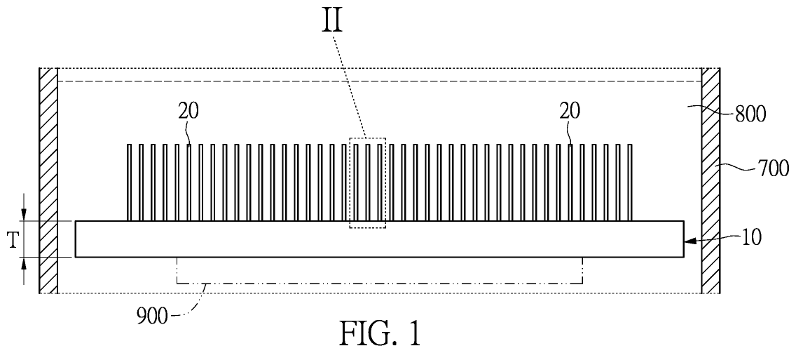

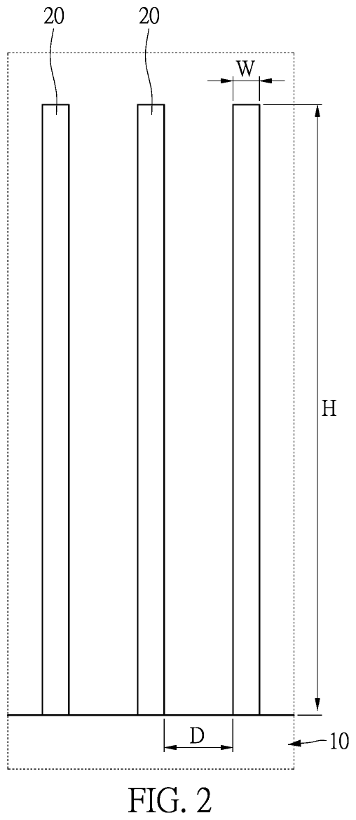

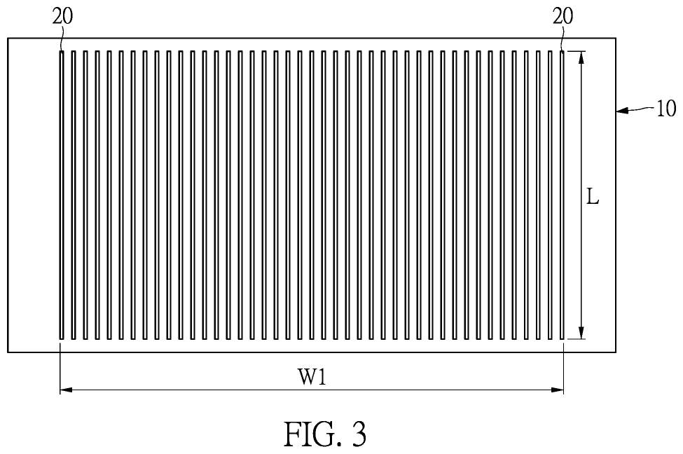

Referring to FIG. 1 to FIG. 3, one embodiment of the present disclosure provides an immersion-type heat dissipation structure having high density heat dissipation fins, which can be used for contacting a heating element 900 immersed in a two-phase coolant 800. As shown in the figures, the immersion-type heat dissipation structure having high density heat dissipation fins provided in this embodiment of the present disclosure includes a heat dissipation substrate 10 and a plurality of sheet-like heat dissipation fins 20. The plurality of sheet-like heat dissipation fins 20 and the heat dissipation substrate 10 are immersed in a sink 700 filled with the two-phase coolant 800. Further, in this embodiment, the two-phase coolant is a FLUORINERT™ that has a low boiling point, and the boiling point of the two-phase coolant 800 ranges from 35° C. to 60° C.

In this embodiment, the heat dissipation substrate 10 can be made of one of copper, copper alloy, and aluminum alloy. The plurality of sheet-like heat dissipation fins 20 are integrally formed on an upper surface of the heat dissipation substrate 10. That is, the plurality of sheet-like heat dissipation fins 20 are integrally formed on the upper surface of the heat dissipation substrate 10 and arranged in high density, so that the plurality of sheet-like heat dissipation fins 20 are integrally formed with the heat dissipation substrate 10 by a same material.

Furthermore, a bottom surface of the heat dissipation substrate 10 can be in contact with the heating element 900 immersed in the two-phase coolant 800. Accordingly, for the heating element 900 immersed in the two-phase coolant 800, heat generated thereby can be removed through an endothermic gasification process of the two-phase coolant 800. In addition, the heat dissipation substrate 10 can be in contact with the heating element 900 and absorb the heat generated thereby. The heat is rapidly conducted to the plurality of sheet-like heat dissipation fins 20 that are integrally formed on the upper surface of the heat dissipation substrate 10 and arranged in very high density. The heat absorbed by the sheet-like heat dissipation fins 20 is then removed through the endothermic gasification process of the two-phase coolant 800, thereby improving an overall immersion-type heat dissipation effect.

In order to properly improve the overall immersion-type heat dissipation effect, through tests, a thickness T of the heat dissipation substrate 10 is from 2 mm to 6 mm, a length L of at least one of the plurality of sheet-like heat dissipation fins 20 is from 60 mm to 120 mm, a width W of at least one of the plurality of sheet-like heat dissipation fins 20 is from 0.1 mm to 0.5 mm, and a height H of at least one of the plurality of sheet-like heat dissipation fins 20 is from 3 mm to 10 mm. Further, a distance D between at least two of the plurality of sheet-like heat dissipation fins 20 that are arranged in parallel to each other is from 0.1 mm to 0.5 mm.

In order to further improve the overall immersion-type heat dissipation effect, through continuous tests, a first predetermined ratio between the distance D and the width W ranges from 0.5:1 to 2:1, a second predetermined ratio between the height H and the width W ranges from 6:1 to 50:1, and a third predetermined ratio between the height H and the distance D ranges from 6:1 to 50:1. The plurality of sheet-like heat dissipation fins 20 are arranged along a width direction that is perpendicular to a length direction of the sheet-like heat dissipation fins 20, so that the plurality of sheet-like heat dissipation fins 20 are arranged to have an arrangement width W1. The arrangement width W1 is between 50 mm and 80 mm.

### Second Embodiment

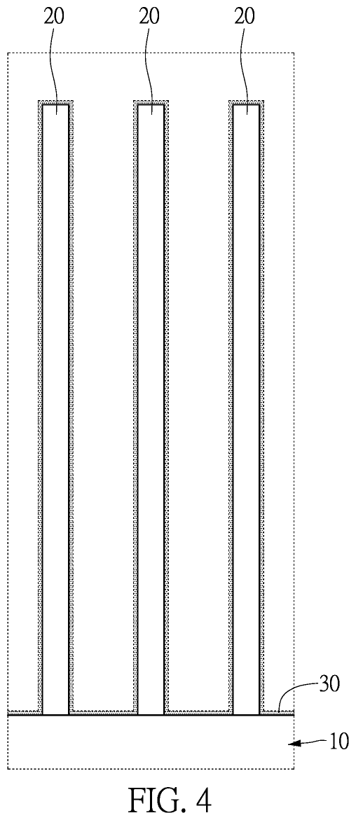

Referring to FIG. 4, a second embodiment of the present disclosure is substantially the same as the first embodiment, and the difference therebetween is described as follows.

In this embodiment, the immersion-type heat dissipation structure having high density heat dissipation fins can further include a thin surface layer 30. The thin surface layer 30 can be formed on the upper surface of the heat dissipation substrate 10 or a surface of the plurality of sheet-like heat dissipation fins 20, or can be formed on both of the aforementioned surfaces. The thin surface layer 30 can be a surface plating layer or a surface coating layer, and can be made of metal such as nickel, titanium, and stainless steel. In this way, an amount of air bubbles generated can be increased, so as to further improve the immersion-type heat dissipation effect.

### Third Embodiment

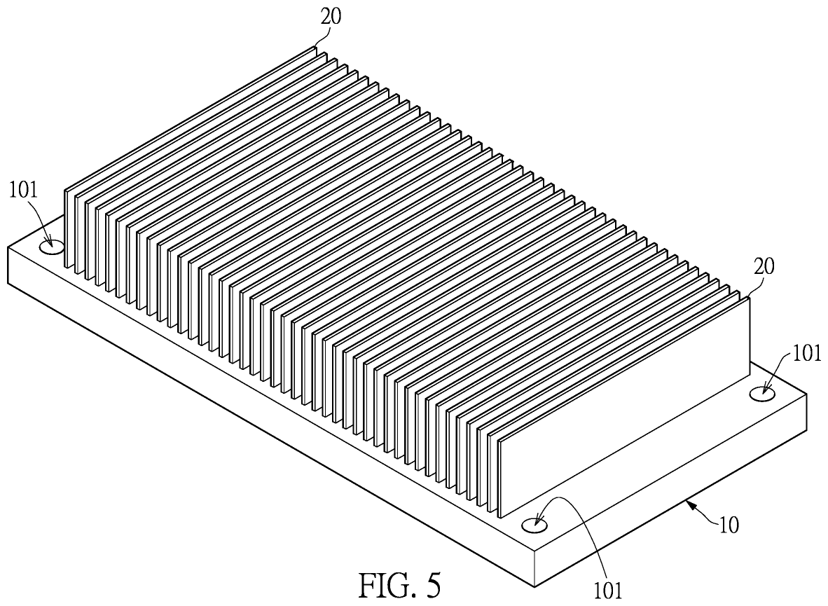

Referring to FIG. 5, a third embodiment of the present disclosure is substantially the same as the first embodiment, and the difference therebetween is described as follows.

In this embodiment, the heat dissipation substrate 10 has a plurality of vertical through holes 101 formed thereon and the plurality of vertical through holes 101 vertically penetrate the heat dissipation substrate 10. The vertical through holes 101 not only can allow fixing of screws, but can also allow air bubbles to pass therethrough. Further, the plurality of vertical through holes 101 can be located at corners of the heat dissipation substrate 10, and a quantity of the plurality of vertical through holes 101 can be four or more.

### Fourth Embodiment

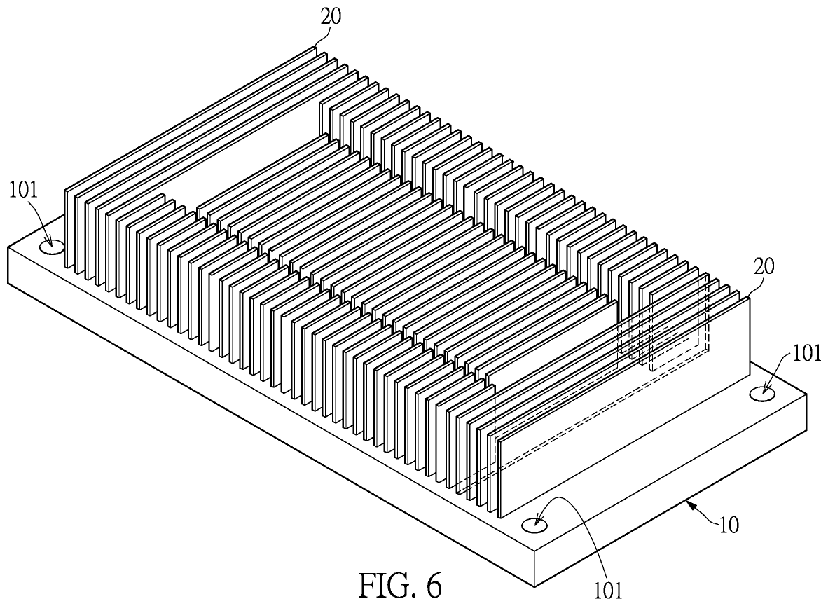

Referring to FIG. 6, a fourth embodiment of the present disclosure is substantially the same as the first embodiment, and the difference therebetween is described as follows.

In this embodiment, after the plurality of sheet-like heat dissipation fins 20 are integrally formed on the upper surface of the heat dissipation substrate 10, the plurality of sheet-like heat dissipation fins 20 are at least partially removed through a second processing operation (e.g., mechanical processing or chemical processing) such that at least one portion of the plurality of sheet-like heat dissipation fins 20 and the remaining sheet-like heat dissipation fins 20 do not have a same height, or the plurality of sheet-like heat dissipation fins 20 on at least one region of the upper surface of the heat dissipation substrate 10 are completely removed through the second processing operation.

### BENEFICIAL EFFECTS OF THE EMBODIMENTS

In conclusion, in the immersion-type heat dissipation structure having high density heat dissipation fins provided by the present disclosure, by virtue of “a thickness of the heat dissipation substrate being from 2 mm to 6 mm,” “a bottom surface of the heat dissipation substrate being in contact with a heating element immersed in a two-phase coolant,” “the plurality of sheet-like heat dissipation fins being integrally formed on an upper surface of the heat dissipation substrate and arranged in high density,” “a length of at least one of the plurality of sheet-like heat dissipation fins being from 60 mm to 120 mm, a width of at least one of the plurality of sheet-like heat dissipation fins being from 0.1 mm to 0.5 mm, a height of at least one of the plurality of sheet-like heat dissipation fins being from 3 mm to 10 mm, and a distance between at least two of the plurality of sheet-like heat dissipation fins that are arranged in parallel to each other being from 0.1 mm to 0.5 mm,” “a first predetermined ratio between the distance and the width ranging from 0.5:1 to 2:1,” “a second predetermined ratio between the height and the width ranging from 6:1 to 50:1,” “a third predetermined ratio between the height and the distance ranging from 6:1 to 50:1,” and “the plurality of sheet-like heat dissipation fins being arranged to have an arrangement width, and the arrangement width being between 50 mm and 80 mm,” the overall immersion-type heat dissipation effect can be effectively improved.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. An immersion-type heat dissipation structure, comprising a heat dissipation substrate and a plurality of sheet-like heat dissipation fins, wherein a thickness of the heat dissipation substrate is from 2 mm to 6 mm, and a bottom surface of the heat dissipation substrate is in contact with a heating element immersed in a two-phase coolant; wherein the plurality of sheet-like heat dissipation fins are integrally formed on an upper surface of the heat dissipation substrate and arranged in high density; wherein a length of at least one of the plurality of sheet-like heat dissipation fins is from 60 mm to 120 mm, a width of at least one of the plurality of sheet-like heat dissipation fins is from 0.1 mm to 0.5 mm, and a height of at least one of the plurality of sheet-like heat dissipation fins is from 3 mm to 10 mm; wherein a distance between at least two of the plurality of sheet-like heat dissipation fins that are arranged in parallel to each other is from 0.1 mm to 0.5 mm; wherein a first predetermined ratio between the distance and the width ranges from 0.5:1 to 2:1, a second predetermined ratio between the height and the width ranges from 6:1 to 50:1, and a third predetermined ratio between the height and the distance ranges from 6:1 to 50:1; wherein the plurality of sheet-like heat dissipation fins are arranged to have an arrangement width, and the arrangement width is between 50 mm and 80 mm.

2. The immersion-type heat dissipation structure according to claim 1, wherein the plurality of sheet-like heat dissipation fins and the heat dissipation substrate are immersed in a sink filled with the two-phase coolant; wherein the two-phase coolant is a FLUORINERT™ that has a low boiling point, and the boiling point of the two-phase coolant ranges from 35° C. to 60° C.

3. The immersion-type heat dissipation structure according to claim 1, wherein the heat dissipation substrate is made of one of copper, copper alloy, and aluminum alloy.

4. The immersion-type heat dissipation structure according to claim 1, further comprising a thin surface layer, wherein the thin surface layer is formed on at least one of the upper surface of the heat dissipation substrate and a surface of the plurality of sheet-like heat dissipation fins.

5. The immersion-type heat dissipation structure according to claim 4, wherein the thin surface layer is one of a surface plating layer and a surface coating layer, and is made of one of nickel, titanium, and stainless steel.

6. The immersion-type heat dissipation structure according to claim 1, wherein the heat dissipation substrate has a plurality of vertical through holes formed thereon, and the plurality of vertical through holes vertically penetrate the heat dissipation substrate.

7. The immersion-type heat dissipation structure according to claim 1, wherein, after the plurality of sheet-like heat dissipation fins are integrally formed on the upper surface of the heat dissipation substrate, the plurality of sheet-like heat dissipation fins are at least partially removed through a second processing operation such that at least one portion of the plurality of sheet-like heat dissipation fins and the remaining sheet-like heat dissipation fins do not have a same height, or the plurality of sheet-like heat dissipation fins on at least one region of the upper surface of the heat dissipation substrate are completely removed through the second processing operation.
